(19) United States
(12) Patent Application Publication
(10) Pub. No.: US 2015/0014657 A1
(43) Pub. Date: Jan. 15, 2015

(54) ORGANIC LIGHT EMITTING DEVICE

(71) Applicant: SAMSUNG DISPLAY CO., LTD., Yongin-City (KR)

(72) Inventors: Yun-Jee PARK, Yongin-City (KR); Ji-Hyun SEO, Yongin-City (KR)

(73) Assignee: SAMSUNG DISPLAY CO., LTD., Yongin-City (KR)

(21) Appl. No.: 14/273,958

(22) Filed: May 9, 2014

(30) Foreign Application Priority Data
Jul. 15, 2013 (KR) 10-2013-0083012

(51) Int. Cl. H01L 51/00; H01L 51/50

(52) U.S. Cl. CPC H01L 51/0052; H01L 51/0061; H01L 51/0072; H01L 51/006; H01L 51/50
USPC 257/40

(57) ABSTRACT

An organic light emitting device includes a first electrode and a second electrode facing to each other; and an organic layer between first electrode and the second electrode. The organic layer includes an assistance layer on the first electrode and an emission layer on the assistance layer. The assistance layer includes a compound represented by Chemical Formula 1:

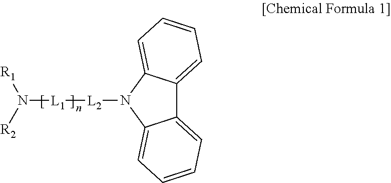

where L₁, L₂, R₁, R₂, and n are as further defined in the specification.

### CROSS-REFERENCE TO RELATED APPLICATION

Korean Patent Application No. 10-2013-0083012, filed on Jul. 15, 2013, in the Korean Intellectual Property Office, and entitled: “Organic Light Emitting Device,” is incorporated by reference herein in its entirety.

### BACKGROUND

1. Field

Embodiments relate to an organic light emitting device.

2. Description of the Related Art

It is desirable to make monitors and televisions thin and lightweight. Accordingly, cathode ray tubes (CRT) have been replaced by liquid crystal displays (LCD). However, liquid crystal displays are non-emissive devices that must be provided with a separate backlight to display images, and may have disadvantages of a limited response time and limited viewing angle.

In this connection, organic light emitting diode (OLED) displays have been developed as a display device that has advantages such as a wide viewing angle, outstanding contrast, and a fast response time.

The organic light emitting device includes two electrodes facing each other and an organic layer interposed between the two electrodes. In the organic light emitting diode device, electrons injected from one electrode and holes injected from another electrode are combined with each other in an emission layer, thereby generating excitons, and energy is outputted from the excitons to thereby emit light. The organic light emitting device may be applicable to various fields including a display device and an illumination system.

### SUMMARY

Embodiments are directed to an organic light emitting device, including a first electrode and a second electrode facing each other, and an organic layer between the first electrode and the second electrode. The organic layer includes an assistance layer on the first electrode and an emission layer on the assistance layer, the assistance layer including a compound represented by Chemical Formula 1:

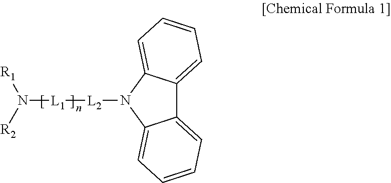

wherein, in Chemical Formula 1, L₁ and L₂ are independently selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group,

R₁ and R₂ are independently selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group, and

n is 0 or 1.

In the compound represented by Chemical Formula 1, n may be 0, and R₁ or R₂ may be condensed to an adjacent substituent or R₁ and R₂ may form a ring.

The compound represented by Chemical Formula 1 may include at least one selected from the compounds represented by Chemical Formula 1-1 to Chemical Formula 1-9:

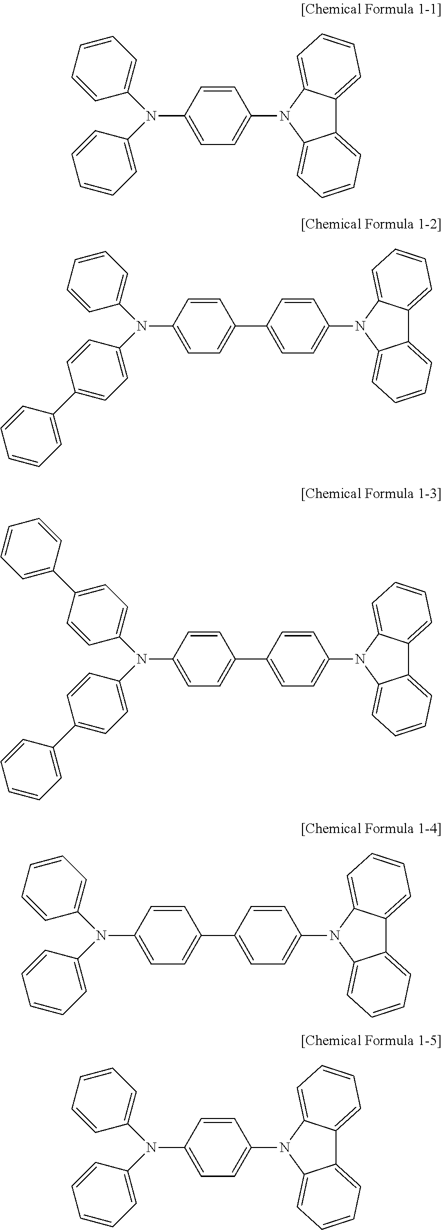 [SMILES: c1ccc(N(c2ccccc2)c2ccc(-n3c4ccccc4c4ccccc43)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccccc2)c2ccc(-c3ccc(-n4c5ccccc5c5ccccc54)cc3)cc2)cc1 ; c1ccc(N(c2ccccc2)c2ccc(-n3c4ccccc4c4ccccc43)cc2)cc1]

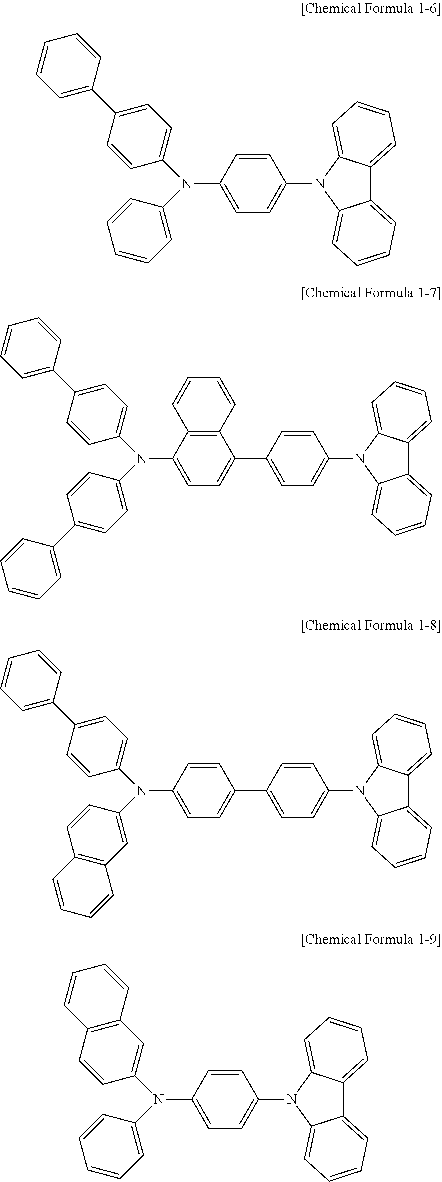 [SMILES: c1ccc(-c2ccc(N(c3ccccc3)c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)c4ccccc34)cc2)cc1 ; c1ccc(-c2ccc(N(c3ccc(-c4ccc(-n5c6ccccc6c6ccccc65)cc4)cc3)c3ccc4ccccc4c3)cc2)cc1 ; c1ccc(N(c2ccc(-n3c4ccccc4c4ccccc43)cc2)c2ccc3ccccc3c2)cc1]

The emission layer may include a host material including a compound represented by Chemical Formula 2:

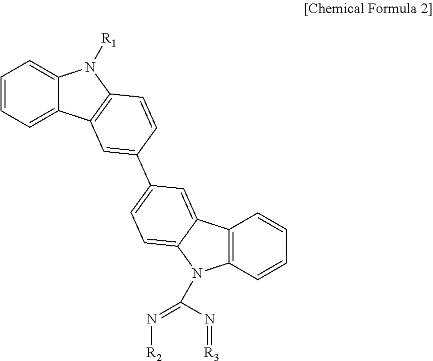

wherein, in Chemical Formula 2,

R₁ to R₃ are selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group.

R₁ to R₃ may be condensed to an adjacent substituent or may form a ring.

The compound represented by Chemical Formula 2 includes at least one selected from the compounds represented by Chemical Formula 2-1 to Chemical Formula 2-6:

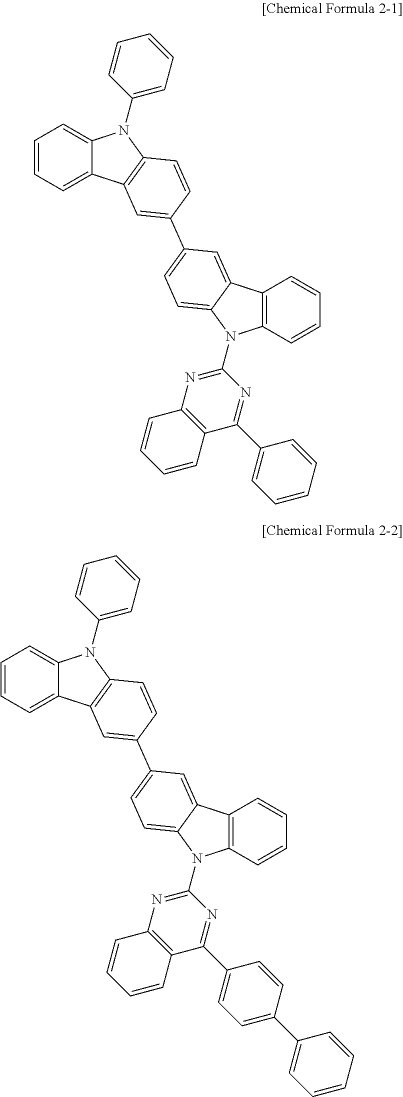 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2ccc(-c3nc(-n4c5ccccc5c5cc(-c6ccc7c(c6)c6ccccc6n7-c6ccccc6)ccc54)nc4ccccc34)cc2)cc1]

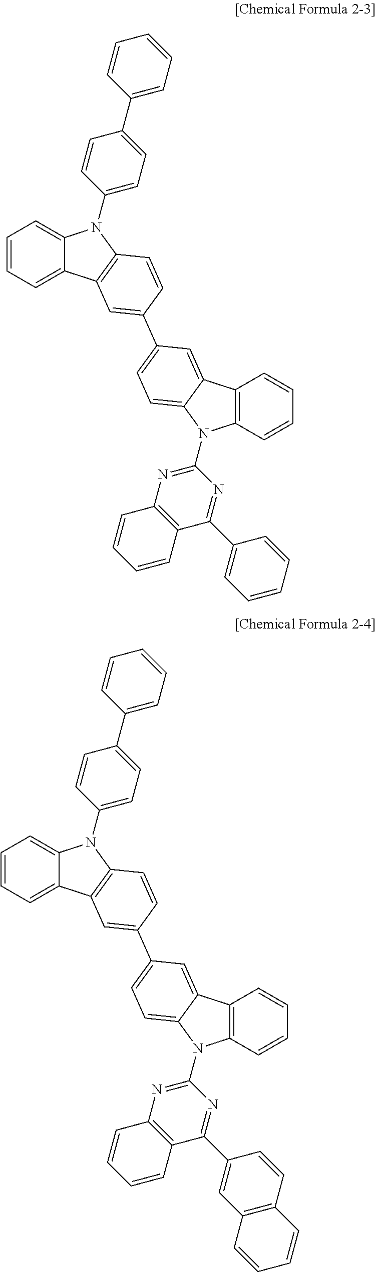 [SMILES: c1ccc(-c2ccc(-n3c4ccccc4c4cc(-c5ccc6c(c5)c5ccccc5n6-c5nc(-c6ccccc6)c6ccccc6n5)ccc43)cc2)cc1 ; c1ccc(-c2ccc(-n3c4ccccc4c4cc(-c5ccc6c(c5)c5ccccc5n6-c5nc(-c6ccc7ccccc7c6)c6ccccc6n5)ccc43)cc2)cc1]

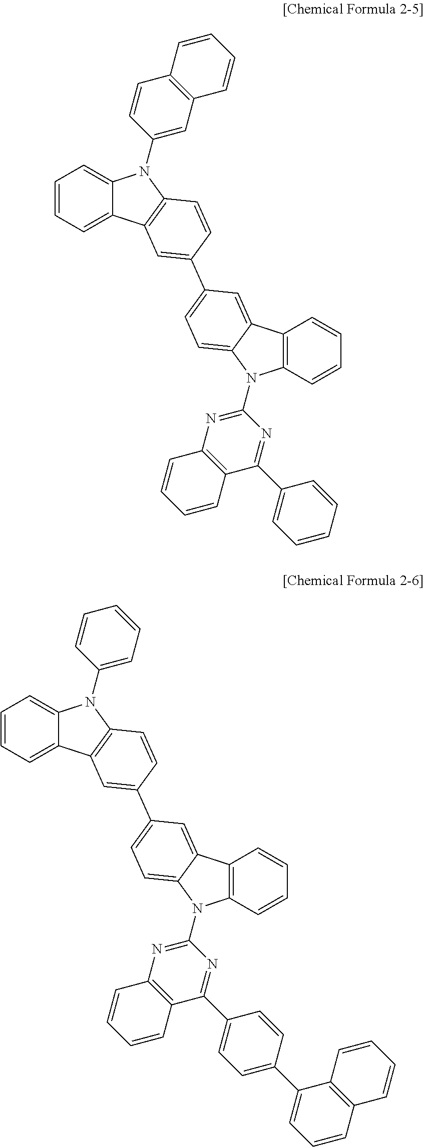 [SMILES: c1ccc(-c2nc(-n3c4ccccc4c4cc(-c5ccc6c(c5)c5ccccc5n6-c5ccc6ccccc6c5)ccc43)nc3ccccc23)cc1 ; c1ccc(-n2c3ccccc3c3cc(-c4ccc5c(c4)c4ccccc4n5-c4nc(-c5ccc(-c6cccc7ccccc67)cc5)c5ccccc5n4)ccc32)cc1]

The emission layer may further include a dopant material.

The dopant material may include a red dopant material, a green dopant material, or a red dopant material.

The first electrode may be an anode, and the second electrode may be a cathode.

The organic layer may include a hole injection layer (HIL) between the first electrode and the assistance layer, a hole transport layer (HTL) between the hole injection layer (HIL) and the assistance layer, and an electron transport layer (ETL) between the emission layer and the second electrode.

### BRIEF DESCRIPTION OF THE DRAWINGS

Features will become apparent to those of skill in the art by describing in detail exemplary embodiments with reference to the attached drawings in which:

FIG. 1 illustrates a view of an organic light emitting device according to an exemplary embodiment.

FIG. 2 illustrates a graph showing a light emitting degree and efficiency of an organic light emitting device according to Exemplary Embodiments 1 to 7 and an organic light emitting device according to a Comparative Example.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

In the present exemplary embodiment, unless otherwise specified, “substituted” refers to a hydrogen atom of a compound substituted with a substituent selected from among halogen atoms (F, Br, Cl, or I), a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxyl group or its salt, a sulfonic acid group or its salt, a phosphoric acid or its salt, an alkyl group, a C2-C16 alkenyl group, a C2-C16 alkynyl group, an aryl group, a C7-C13 arylalkyl group, a C1-C4 oxyalkyl group, a C1-C20 heteroalkyl group, a C3-C20 heteroaryl alkyl group, a cycloalkyl group, a C3-C15 cycloalkenyl group, a C6-C15 cycloalkynyl group, a heterocycloalkyl group, and combinations thereof.

Also, unless otherwise specified, “hetero” refers to containing one to three hetero atoms selected from among N, O, S, and P.

In the drawings, the thickness and/or relative thickness of the elements may be exaggerated in order to clarify embodiments. Also, the expressions related to positions such as “upper part”, “lower part”, or the like are relatively used for clarification, without limiting absolute positions among the elements.

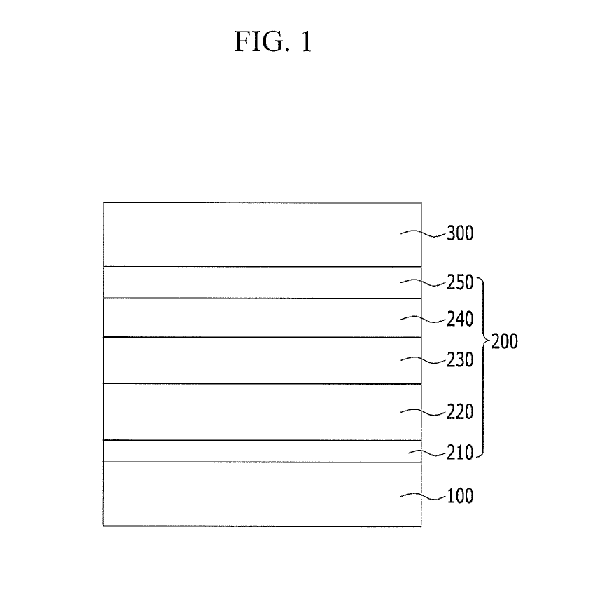

An organic light emitting device according to an exemplary embodiment will now be described with reference to FIG. 1.

FIG. 1 illustrates a view of an organic light emitting device according to an exemplary embodiment.

Referring to FIG. 1, an organic light emitting device according to the present exemplary embodiment may include a first electrode 100, a second electrode 300 facing the first electrode 100, and an organic layer 200 interposed between the first electrode 100 and the second electrode 300.

A substrate (not shown) may be disposed at the first electrode 100 side or the second electrode 300 side. The substrate may include glass, a polymer, or combinations thereof.

The first electrode 100 may be an anode, and the second electrode 300 may be a cathode. The first electrode 100 and the second electrode 300 may be transparent or non-transparent electrodes. For example, the first electrode 100 and the second electrode 300 may be a transparent electrode made of ITO (indium tin oxide), IZO (indium zinc oxide), or combinations thereof, or a non-transparent electrode made of aluminum (Al), silver (Ag), magnesium (Mg), or combinations thereof.

The organic layer 200 may include a hole injection layer (HIL) 210, a hole transport layer (HTL) 220, an assistance layer 230, an emission layer 240, and an electron transport layer (ETL) 250 sequentially disposed on the first electrode 100.

The hole injection layer (HIL) 210 and the hole transport layer (HTL) 220 may be disposed between the first electrode 100 and the emission layer 240, such that holes may be easily transmitted from the first electrode 100 to the emission layer 240.

The hole injection layer (HIL) 210 may be formed of a hole injection material. For example, the hole injection material may be a phthalocyanine compound such as copper phthalocyanine or the like, m-MTDATA (4,4′,4″-tris(3-methylphenylphenylamino)triphenylamine), NPB (N,N′-di(1-naphthyl)-N,N-diphenylbenzidine), TDATA, 2T-NATA, Pani/DBSA (polyaniline/dodecylbenzene sulfonic acid:polyaniline/dodecylbenzene sulfonic acid), PEDOT/PSS (poly(3,4-ethylene dioxythiophene)/poly(4-styrene sulfonate):poly(3,4-ethylene dioxythiophene)/poly(4-styrene sulfonate)), Pani/CSA (polyaniline/camphor sulfonic acid:polyaniline/camphor sulfonic acid), or Pani/PSS ((polyaniline)/poly(4-styrene sulfonate)).

The hole transport layer (HTL) 220 may contain a hole transport material. For example, the hole transport material may be a carbazole derivative such as N-phenylcarbazole, polyvinylcarbazole, or the like, and an amine derivative having an aromatic condensed ring such as NPB, N,N′-bis(3-methylphenyl)-N,N′-diphenyl-[1,1-biphenyl]-4,4′-diamine (TPD), tris(4-carbazoyl-9-ylphenyl)amine (TCTA), or the like.

The assistance layer 230 may be disposed at the hole transport layer (HTL) 220 and the emission layer 240 to adjust a balance of the charges in the organic light emitting device thereby preventing roll-off generation.

The assistance layer 230 may include a compound represented by Chemical Formula 1 below.

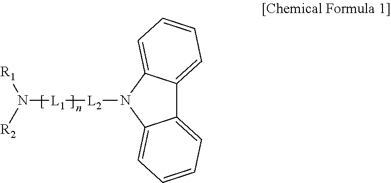

In Chemical Formula 1, L₁ and L₂ may be independently selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group, and n may be 0 or 1.

When n is 0, L₂ and N may be directly connected.

Further, R1 and R2 may be independently selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group.

R₁ and R₂ may be condensed to the adjacent substituent or may form a ring.

As examples, a compound represented by Chemical Formula 1 may be at least one selected from compounds represented by Chemical Formula 1-1 to Chemical Formula 1-9. The compound represented by Chemical Formula 1-1 to Chemical Formula 1-9 may be independently used, at least two or more may be mixed, or at least one may be mixed with a different compound.

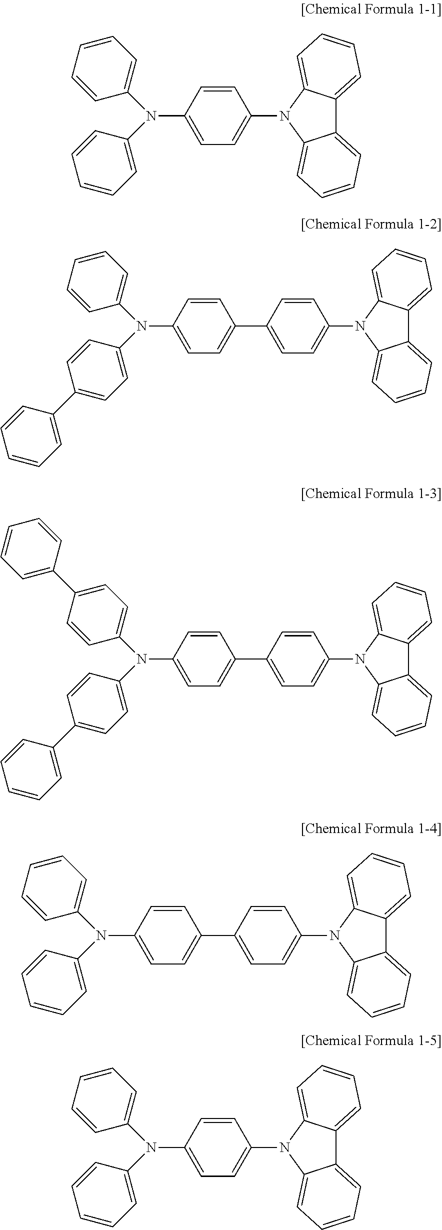 [SMILES: c1ccc(N(c2ccccc2)c2ccc(-n3c4ccccc4c4ccccc43)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccccc2)c2ccc(-c3ccc(-n4c5ccccc5c5ccccc54)cc3)cc2)cc1 ; c1ccc(N(c2ccccc2)c2ccc(-n3c4ccccc4c4ccccc43)cc2)cc1]

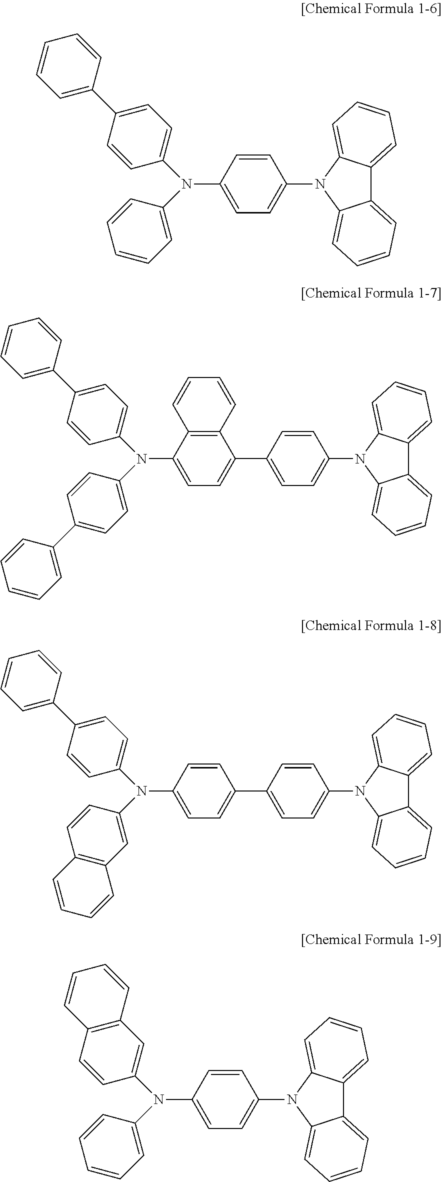 [SMILES: c1ccc(-c2ccc(N(c3ccccc3)c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)c4ccccc34)cc2)cc1 ; c1ccc(-c2ccc(N(c3ccc(-c4ccc(-n5c6ccccc6c6ccccc65)cc4)cc3)c3ccc4ccccc4c3)cc2)cc1 ; c1ccc(N(c2ccc(-n3c4ccccc4c4ccccc43)cc2)c2ccc3ccccc3c2)cc1]

The emission layer 240 may be made of a host material and a dopant. The dopant may include a material that emits one among primary colors such as red, green, and blue.

The host material may include a compound represented by Chemical Formula 2.

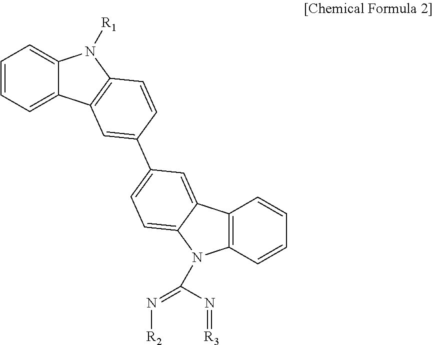

In Chemical Formula 2, R₁ to R₃ may be selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group.

Also, R₁ to R₃ may be condensed to an adjacent substituent or may form the ring.

For example, the compound represented by Chemical Formula 2 may be at least one selected from compounds represented by Chemical Formula 2-1 to Chemical Formula 2-6. The compound represented by Chemical Formula 2-1 to Chemical Formula 2-6 may be independently used, at least two or more may be mixed, or at least one may be mixed with a different compound.

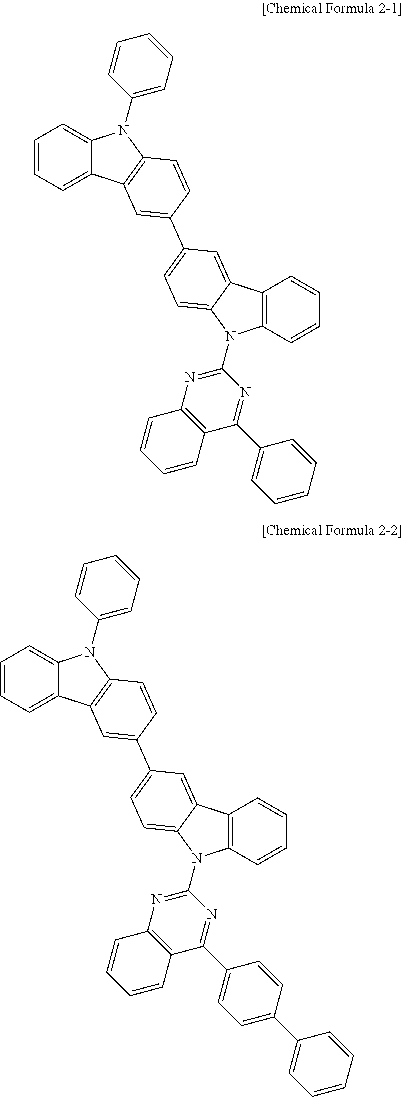 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2ccc(-c3nc(-n4c5ccccc5c5cc(-c6ccc7c(c6)c6ccccc6n7-c6ccccc6)ccc54)nc4ccccc34)cc2)cc1]

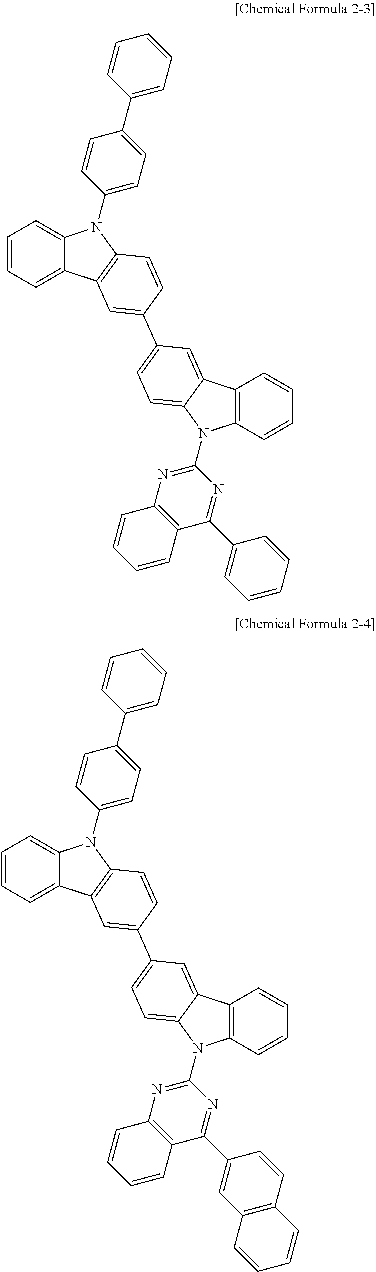 [SMILES: c1ccc(-c2ccc(-n3c4ccccc4c4cc(-c5ccc6c(c5)c5ccccc5n6-c5nc(-c6ccccc6)c6ccccc6n5)ccc43)cc2)cc1 ; c1ccc(-c2ccc(-n3c4ccccc4c4cc(-c5ccc6c(c5)c5ccccc5n6-c5nc(-c6ccc7ccccc7c6)c6ccccc6n5)ccc43)cc2)cc1]

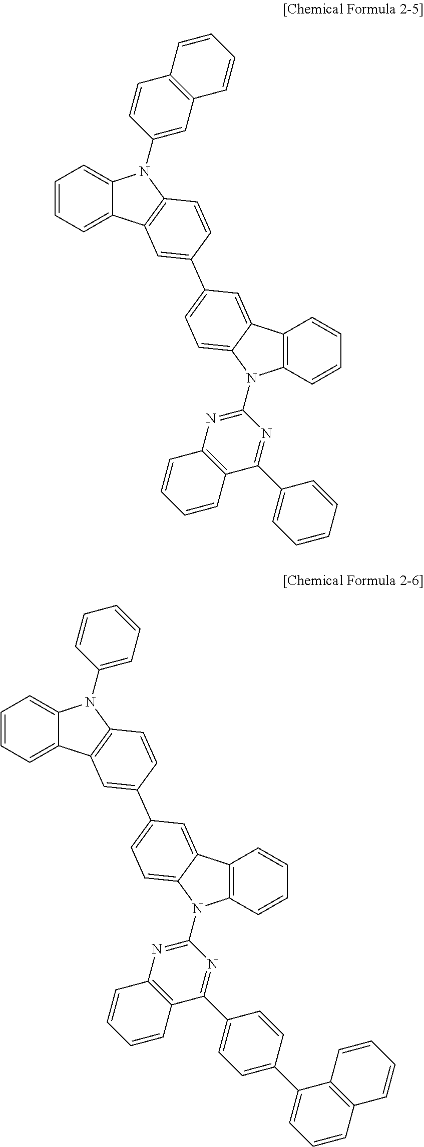 [SMILES: c1ccc(-c2nc(-n3c4ccccc4c4cc(-c5ccc6c(c5)c5ccccc5n6-c5ccc6ccccc6c5)ccc43)nc3ccccc23)cc1 ; c1ccc(-n2c3ccccc3c3cc(-c4ccc5c(c4)c4ccccc4n5-c4nc(-c5ccc(-c6cccc7ccccc67)cc5)c5ccccc5n4)ccc32)cc1]

As examples, a red dopant may include PtOEP, Ir(piq)₃, Btp₂Ir(acac), DCJTB, or the like.

As examples, a green dopant may include Ir(ppy)₃(ppy=phenyl), Ir(ppy)₂(acac), Ir(mpyp)₃, C545T, or the like.

As examples, a blue dopant may include F₂Irpic, (F₂ ppy)2Ir(tmd), Ir(dfppz)₃, ter-fluorene, 4,4′-bis(4-diphenylaminostyryl)biphenyl (DPAVBi), 2,5,8,11-tetra-tert-butyl perylene (TBP), or the like.

For example, the emission layer 240 of the organic light emitting device may include the compound represented by Chemical Formula 2 as the host material, and may be a red emission layer doped with the red dopant.

The electron transport layer (ETL) 250 may be disposed between the emission layer 240 and the second electrode 300. Thereby, electrons may be easily injected from the second electrode 300 to the emission layer 240. The electron transport layer (ETL) 250 may include an electron transport material. For example, the disclosed material may be a quinoline derivative such as aluminum tris(8-hydroxyquinoline) (Alq₃), TAZ, or BAlq.

The electron injection layer (EIL) may be disposed between the electron transport layer (ETL) 250 and the second electrode 300 such that the electrons may be easily injected from the second electrode 300 to the emission layer 240. The electron injection layer (EIL) may be made of an electron injection material, for example, lithium fluoride (LiF), lithium quinolate (Liq), oxadiazole, triazole, or triazine.

As described above, the assistance layer 230 made of the compound represented by Chemical Formula 1 may be disposed between the hole transport layer (HTL) 220 and the emission layer 240. The compound represented by Chemical Formula 2 may be used as the host material of the emission layer 240, thereby adjusting the balance of the elements in the organic light emitting device.

Accordingly, the generation of a roll-off phenomenon may be reduced. Further, the efficiency of the organic device may be improved, and the life-span may be increased.

The following Examples and Comparative Examples are provided in order to highlight characteristics of one or more embodiments, but it is to be understood that the Examples and Comparative Examples are not to be construed as limiting the scope of the embodiments, nor are the Comparative Examples to be construed as being outside the scope of the embodiments. Further, it is to be understood that the embodiments are not limited to the particular details described in the Examples and Comparative Examples.

### Exemplary Embodiment 1

ITO (indium tin oxide) was cut into a size of 50 mm×50 mm×0.5 mm and was subjected to an ultrasonic wave cleaning process for about ten minutes using isopropyl alcohol and pure water to form an anode.

2T-NATA (4,4′,4″-tris[2-naphthyl(phenyl)amino]triphenylamine) having a thickness of 100 Å was vacuum-deposited on the anode to form a hole injection layer (HIL). NPB (N,N-di(1-naphthyl)-N,N′-diphenylbenzidine) having a thickness of 1350 Å was vacuum-deposited on the hole injection layer (HIL) to form a hole transport layer (HTL).

The compound represented by Chemical Formula 1-3 and having a thickness of 700 Å was vacuum-deposited on the hole transport layer (HTL) to form an assistance layer. The compound represented by Chemical Formula 2-2, serving as a host material, and Ir(piq)₃ (Tris[1-phenylisoquinoline-C2,N]iridium(III), serving as a red phosphorescent dopant of a dopant material, were simultaneously subjected to vacuum deposition in a weight ratio of 1:0.04 to form an emission layer having a thickness of 400 Å on the assistance layer.

Alga (Tris(8-hydroxyquinolinato)aluminum) was subjected to vacuum deposition to form an electron transport layer (ETL) with a thickness of 300 Å on the emission layer. Then, Al was subjected to vacuum deposition to form a cathode with a thickness of 1200 Å on the electron transport layer (ETL).

Thereby, the organic light emitting device is manufactured.

### Exemplary Embodiment 2

An organic light emitting diode device was manufactured by using substantially the same method as in Exemplary Embodiment 1, except for using the compound represented by Chemical Formula 1-1 as the assistance layer.

### Exemplary Embodiment 3

An organic light emitting diode device was manufactured by using substantially the same method as in Exemplary Embodiment 1, except for using the compound represented by Chemical Formula 1-2 as the assistance layer.

### Exemplary Embodiment 4

An organic light emitting diode device was manufactured by using substantially the same method as in Exemplary Embodiment 1, except for using the compound represented by Chemical Formula 1-4 as the assistance layer.

### Exemplary Embodiment 5

An organic light emitting diode device was manufactured by using substantially the same method as in Exemplary Embodiment 1, except for using the compound represented by Chemical Formula 1-5 as the assistance layer.

### Exemplary Embodiment 6

An organic light emitting diode device was manufactured by using substantially the same method as in Exemplary Embodiment 1, except for using the compound represented by Chemical Formula 2-1 as the host material of the emission layer.

### Exemplary Embodiment 7

An organic light emitting diode device was manufactured by using substantially the same method as in Exemplary Embodiment 2, except for using the compound represented by Chemical Formula 2-1 as the host material of the emission layer.

### Comparative Example

An organic light emitting diode device was manufactured by using substantially the same method as in Exemplary Embodiment 1, except for vacuum-depositing NPB with a thickness of 2100 Å to form the hole transport layer (HTL) and using CBP (4,4′-Bis(9-carbazolyl)-1,1′-biphenyl) as the host material of the emission layer without the assistance layer.

The driving voltage, the efficiency, and the life-span of the organic light emitting device according to Exemplary Embodiments 1 to 7 and the organic light emitting device according to the comparative example were measured. The measurement results are shown in Table 1.

TABLE 1

| | | | Driving | Current | |
|---|---|---|---|---|---|
| | Assistance layer | Host | voltage | efficiency | Life-span |
| | material | material | (V) | (Cd/A) | (T97, hours) |
| Comparative | — | CBP | 4.8 | 27.6 | 302 |
| Example | | | | | |
| Exemplary | Chemical Formula | Chemical | 4.0 | 43.9 | 730 |
| Embodiment 1 | 1-3 | Formula 2-2 | | | |
| Exemplary | Chemical Formula | Chemical | 4.5 | 33.9 | 520 |
| Embodiment 2 | 1-1 | Formula 2-2 | | | |
| Exemplary | Chemical Formula | Chemical | 4.3 | 38.8 | 601 |
| Embodiment 3 | 1-2 | Formula 2-2 | | | |
| Exemplary | Chemical Formula | Chemical | 4.3 | 32.7 | 528 |
| Embodiment 4 | 1-4 | Formula 2-2 | | | |
| Exemplary | Chemical Formula | Chemical | 4.5 | 34.3 | 545 |
| Embodiment 5 | 1-5 | Formula 2-2 | | | |
| Exemplary | Chemical Formula | Chemical | 4.2 | 41.5 | 684 |
| Embodiment 6 | 1-3 | Formula 2-1 | | | |
| Exemplary | Chemical Formula | Chemical | 4.4 | 35.1 | 560 |
| Embodiment 7 | 1-1 | Formula 2-1 | | | |

Referring to Table 1, in the organic light emitting device according to Exemplary Embodiments 1 to 7, the driving voltage is shown to be lower, and the current efficiency and the life-span are shown to be greater, compared with the organic light emitting device according to the Comparative Example.

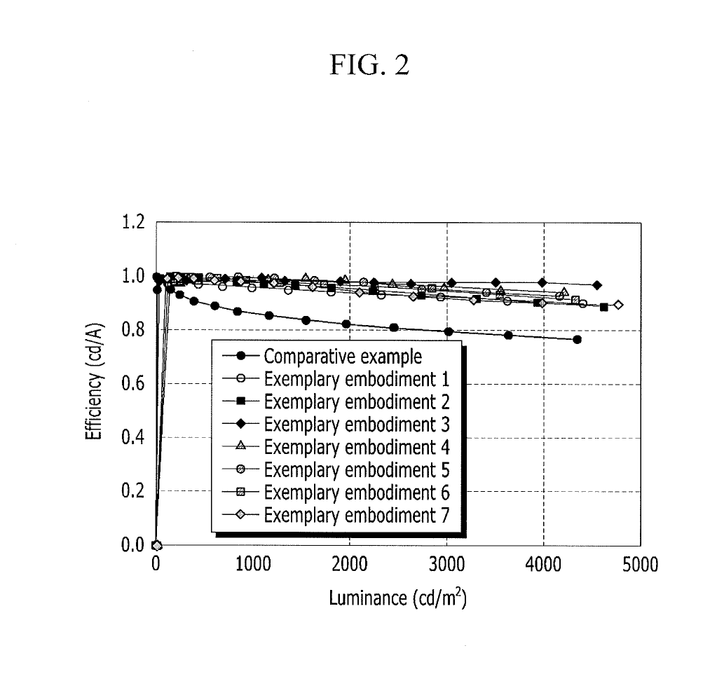

The efficiency according to a light emitting degree for the organic light emitting device according to Exemplary Embodiments 1 to 7 and the organic light emitting device according to the comparative example was measured. The measurement results are shown in FIG. 2.

FIG. 2 illustrates a graph showing a light emitting degree (luminance, in units of cd/m²) and efficiency (cd/A) of an organic light emitting device according to Exemplary Embodiments 1 to 7 and an organic light emitting device according to a Comparative Example.

Referring to FIG. 2, in the organic light emitting device according to the Comparative Example, compared with the organic light emitting device according to Exemplary Embodiments 1 to 7, as the light emitting degree was increased, the efficiency was decreased.

In the case of the organic light emitting device according to the Comparative Example, the driving voltage was decreased by the hole injection layer (HIL) such that the initial efficiency was shown to be good. However, without being bound to any particular theory, it is believed that the charge balance in the elements was poor such that the roll-off phenomenon was generated, and thereby the efficiency was gradually reduced.

In contrast, by using the assistance layer in the organic light emitting devices according to Exemplary Embodiments 1 to 7, as the light emitting degree was increased, the reduction of the efficiency was slight such that it may be confirmed that the generation of the roll-off phenomenon may be reduced or avoided.

By way of summation and review, in an organic light emitting device, characteristics of a material forming the organic layer may largely affect electrical characteristics of the organic light emitting device.

Embodiments provide an organic light emitting device having high efficiency and a long life-span. According embodiments, by forming an assistance layer between the emission layer and the hole transport layer (HTL) including the compound represented by Chemical Formula 1 and the host in the emission layer including the compound represented by Chemical Formula 2, the efficiency of the organic light emitting device may be improved and the life-span may be increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An organic light emitting device, comprising:
a first electrode and a second electrode facing each other; and
an organic layer between the first electrode and the second electrode,
wherein the organic layer includes an assistance layer on the first electrode and an emission layer on the assistance layer, the assistance layer including a compound represented by Chemical Formula 1: 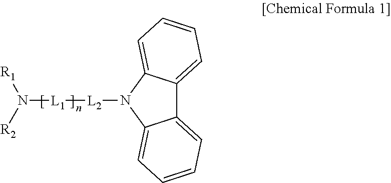
wherein, in Chemical Formula 1, L₁ and L₂ are independently selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group,
R₁ and R₂ are independently selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group, and
n is 0 or 1.

2. The organic light emitting device as claimed in claim 1, wherein in the compound represented by Chemical Formula 1,
n is 0, and
R₁ or R₂ is condensed to an adjacent substituent or R₁ and R₂ form a ring.

3. The organic light emitting device as claimed in claim 2, wherein the compound represented by Chemical Formula 1 includes at least one selected from the compounds represented by Chemical Formula 1-1 to Chemical Formula 1-9:

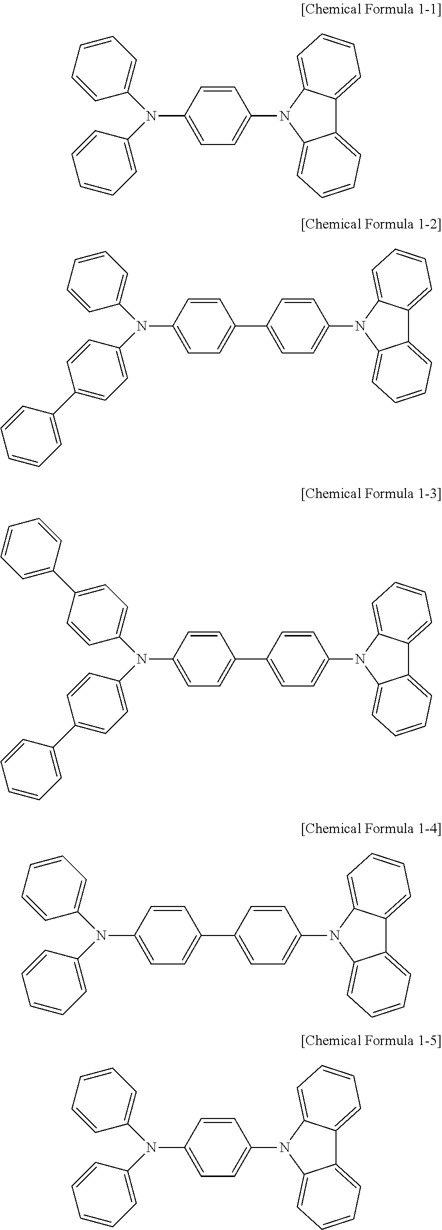 [SMILES: c1ccc(N(c2ccccc2)c2ccc(-n3c4ccccc4c4ccccc43)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccccc2)c2ccc(-c3ccc(-n4c5ccccc5c5ccccc54)cc3)cc2)cc1 ; c1ccc(N(c2ccccc2)c2ccc(-n3c4ccccc4c4ccccc43)cc2)cc1]

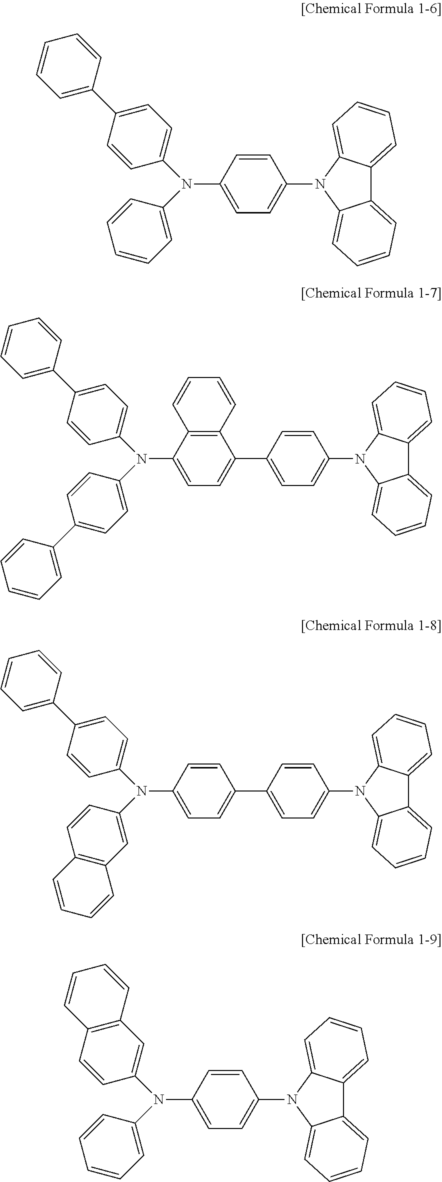 [SMILES: c1ccc(-c2ccc(N(c3ccccc3)c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)c4ccccc34)cc2)cc1 ; c1ccc(-c2ccc(N(c3ccc(-c4ccc(-n5c6ccccc6c6ccccc65)cc4)cc3)c3ccc4ccccc4c3)cc2)cc1 ; c1ccc(N(c2ccc(-n3c4ccccc4c4ccccc43)cc2)c2ccc3ccccc3c2)cc1]

4. The organic light emitting device as claimed in claim 1, wherein the emission layer includes a host material including a compound represented by Chemical Formula 2: 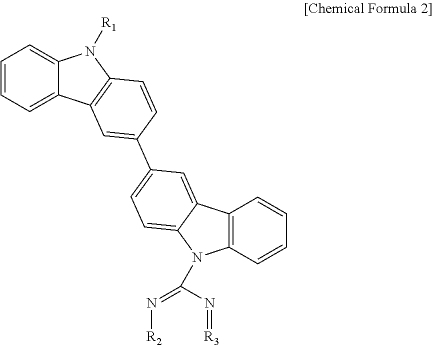
wherein, in Chemical Formula 2,
R1 to R₃ are selected from the group of an amino group, a nitro group, a nitrile group, a C1 to C40 alkyl group, a C2 to C40 alkenyl group, a C2 to C40 alkynyl group, a nitro group, a nitrile group, a C1 to C40 alkyl group, a C2 to C40 alkenyl group, a C2 to C40 alkynyl group, a C5 to C40 aryl group, a C1 to C40 heteroaryl group, a C1 to C40 alkoxy group, a C5 to C40 aryloxy group, a C1 to C40 alkylamino group, a C5 to C40 arylamino group, a C5 to C40 diarylamino group, a C5 to C40 heteroarylamino group, a C2 to C40 diheteroarylamino group, a C6 to C40 arylalkyl group, a C6 to C40 heteroarylalkyl group, a C3 to C40 cycloalkyl group, a C1 to C40 halogenalkyl group, a C3 to C40 heterocycloalkyl group, a C3 to C40 alkylsilyl group, a C3 to C40 arylsilyl group, and a C3 to C40 heteroarylsilyl group.

5. The organic light emitting device as claimed in claim 4, wherein R1 to R₃ are condensed to an adjacent substituent or form a ring.

6. The organic light emitting device as claimed in claim 5, wherein the compound represented by Chemical Formula 2 includes at least one selected from the compounds represented by Chemical Formula 2-1 to Chemical Formula 2-6:

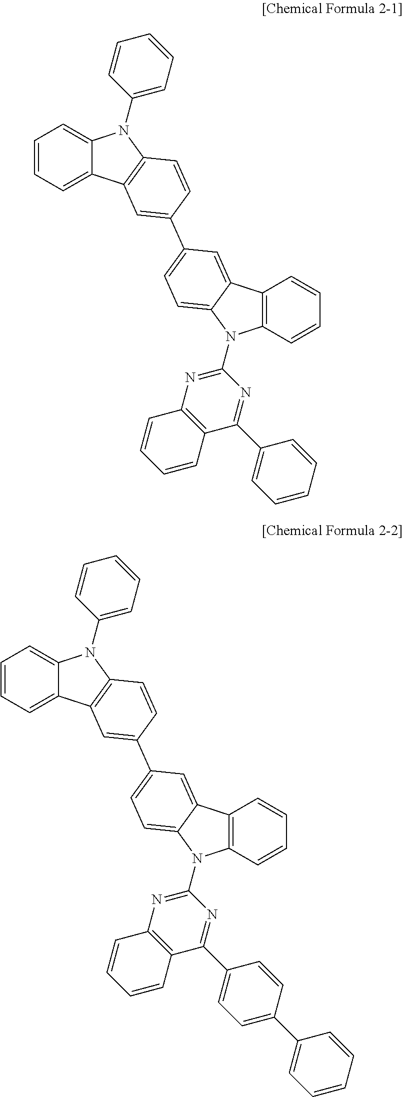 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2ccc(-c3nc(-n4c5ccccc5c5cc(-c6ccc7c(c6)c6ccccc6n7-c6ccccc6)ccc54)nc4ccccc34)cc2)cc1]

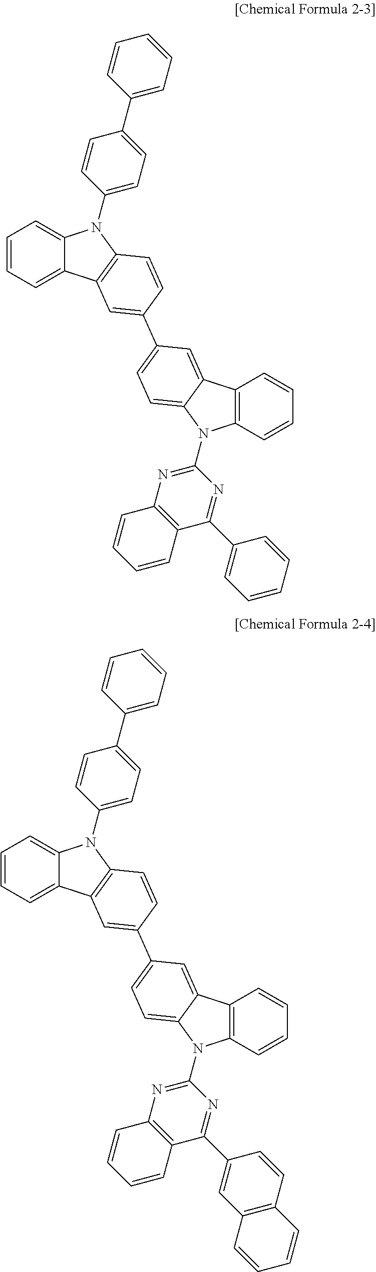 [SMILES: c1ccc(-c2ccc(-n3c4ccccc4c4cc(-c5ccc6c(c5)c5ccccc5n6-c5nc(-c6ccccc6)c6ccccc6n5)ccc43)cc2)cc1 ; c1ccc(-c2ccc(-n3c4ccccc4c4cc(-c5ccc6c(c5)c5ccccc5n6-c5nc(-c6ccc7ccccc7c6)c6ccccc6n5)ccc43)cc2)cc1]

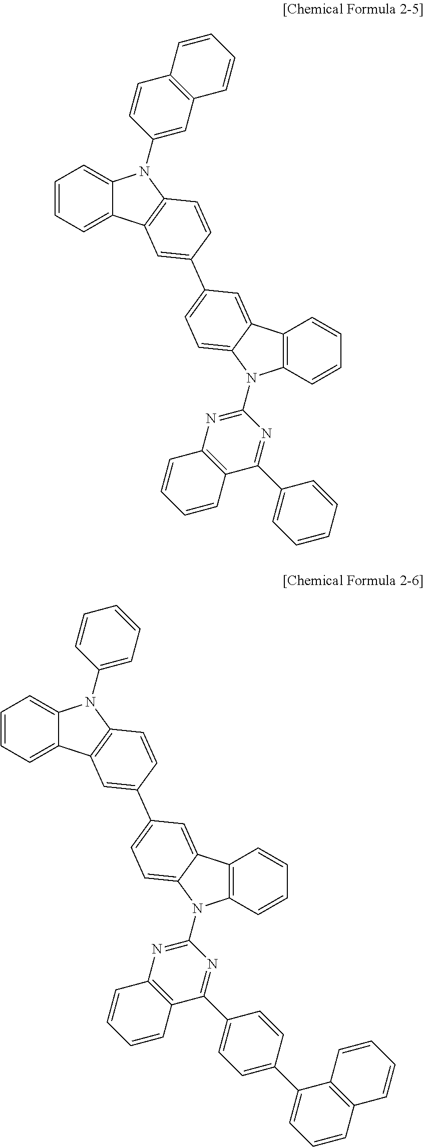 [SMILES: c1ccc(-c2nc(-n3c4ccccc4c4cc(-c5ccc6c(c5)c5ccccc5n6-c5ccc6ccccc6c5)ccc43)nc3ccccc23)cc1 ; c1ccc(-n2c3ccccc3c3cc(-c4ccc5c(c4)c4ccccc4n5-c4nc(-c5ccc(-c6cccc7ccccc67)cc5)c5ccccc5n4)ccc32)cc1]

7. The organic light emitting device as claimed in claim 6, wherein the emission layer further includes a dopant material.

8. The organic light emitting device as claimed in claim 7, wherein the dopant material includes a red dopant material, a green dopant material, or a red dopant material.

9. The organic light emitting device as claimed in claim 1, wherein the first electrode is an anode, and the second electrode is a cathode.

10. The organic light emitting device as claimed in claim 9, wherein the organic layer includes:
a hole injection layer (HIL) between the first electrode and the assistance layer;
a hole transport layer (HTL) between the hole injection layer (HIL) and the assistance layer; and
an electron transport layer (ETL) between the emission layer and the second electrode.
